(19) United States
(12) Patent Application Publication
(10) Pub. No.: US 2003/0106708 A1
(43) Pub. Date: Jun. 12, 2003

(54) Heat sink securing means with back plate

(76) Inventor: Hao-Yun Ma, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/097,284

(22) Filed: Mar. 12, 2002

(30) Foreign Application Priority Data
Dec. 12, 2001 (TW) 90221697

(51) Int. Cl. H05K 1/00

(52) U.S. Cl. 174/252

(57) ABSTRACT

Heat sink securing means adapted to accommodate a heat dispersing device. The securing means has a circuit board (2) sandwiched therein. The securing means comprises a retention module (1) and a plastic back plate (3). The retention module defines a plurality of countersink holes (12) therein. The back plate has a plurality of posts (32) extending upwardly therefrom, for insertion through the circuit board and the countersink holes of the retention module. Protruding ends of the posts are heated and melted. The retention module, circuit board and back plate are thereby firmly and securely combined together.

### BACKGROUND OF THE INVENTION

1. Field of the Invention

The present invention relates to means for securing a heat sink onto a heat-generating electronic device mounted on a circuit board, and particularly to securing means including a back plate which has simple configuration.

2. Description of Related Art

In a typical personal computer, a heat sink is attached to a central processing unit (CPU) mounted on a mother board, for dispersing heat generated from the CPU. The heat sink is often secured to the mother board by a retention module, with the heat sink being received in the retention module.

The retention module is firstly attached to the mother board with screws. This often distorts or damages the mother board. To overcome this problem, a back plate is attached to a back side of the mother board. The back plate reinforces the mother board. However, it is troublesome and time-consuming to assemble all these components together.

Therefore, new securing means to overcome the above-mentioned problems is desired.

### SUMMARY OF THE INVENTION

Accordingly, an object of the present invention is to provide heat sink securing means having compact configuration.

Another object of the present invention is to provide heat sink securing means which is quickly and conveniently assembled.

In order to achieve the objects set out above, heat sink securing means in accordance with the present invention is adapted to accommodate a heat dispersing device. The securing means has a circuit board sandwiched therein. The securing means comprises a retention module and a plastic back plate. The retention module defines a plurality of countersink holes therein. The back plate has a plurality of posts extending upwardly therefrom, for insertion through the circuit board and the countersink holes of the retention module. Protruding ends of the posts are heated and melted. The retention module, circuit board and back plate are thereby firmly and securely combined together.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an exploded perspective view of securing means in accordance with the present invention, together with an intermediate circuit board; and

FIGS. 2 to 4 are views of progressive stages of assembly of the securing means and circuit board of FIG. 1.

### DETAILED DESCRIPTION OF THE INVENTION

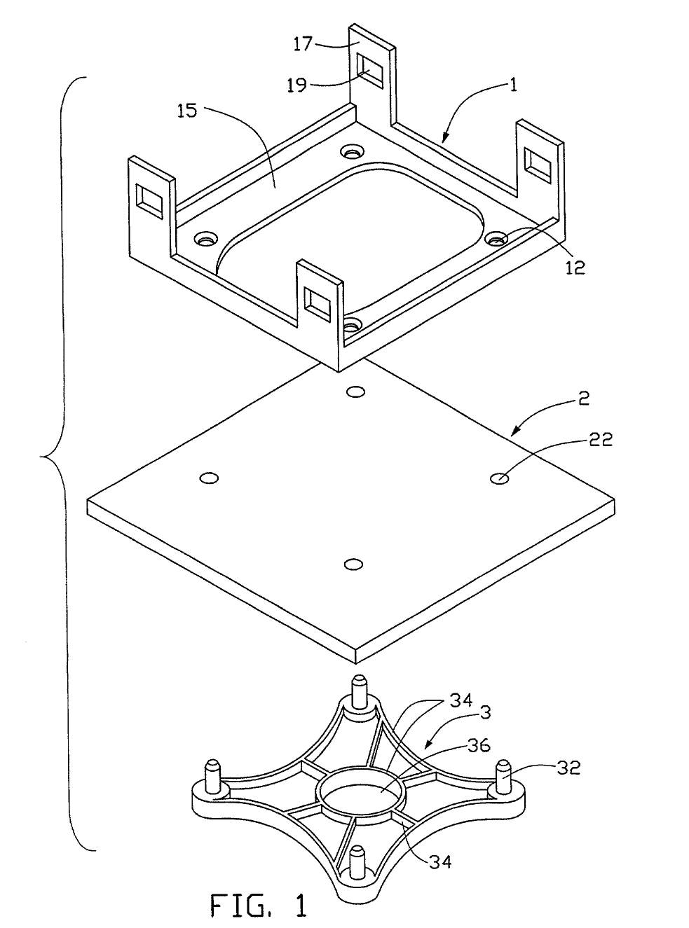

FIG. 1 is an exploded view of securing means in accordance with a preferred embodiment of the present invention. The securing means includes a heat sink retention module 1 and a back plate 3. A circuit board 2 is sandwiched between the retention module 1 and the back plate 3. A plurality of through holes 22 is defined in the circuit board 3.

The retention module 1 has a rectangular base 15, and four columns 17 extending upwardly from four comers of the base 15 respectively. A locking slot 19 is defined in each column 17, for engagement with a heat sink (not shown) received in the retention module 1. A countersink hole 12 is defined at each corner of the base 15.

The back plate 3 is plastic, and generally rhomboid-shaped. A post 32 extends upwardly from each of four evenly-spaced extremities of the back plate 3. A length of each post 32 is sufficient for the post 32 to fully penetrate both a corresponding through hole 22 of the circuit board 2 and a corresponding countersink hole 12 of the base 15 of the retention module 1. The length of the post 32 is preferably sufficient for the post 32 to projects slightly out from the corresponding countersink hole 12 of the base 15. The post 32 has a cone-shaped end for facilitating insertion into the corresponding through hole 22 and corresponding countersink hole 12. The post 32 can be hollow or solid. An opening 36 is defined in a center of the back plate 3. A plurality of ribs 34 is formed on the back plate 3, for reinforcing the back plate 3.

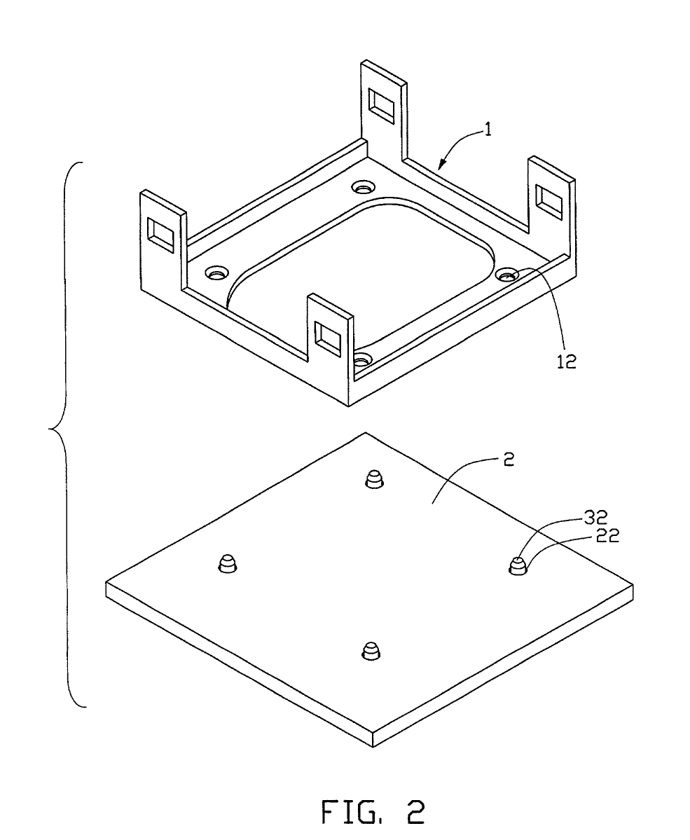

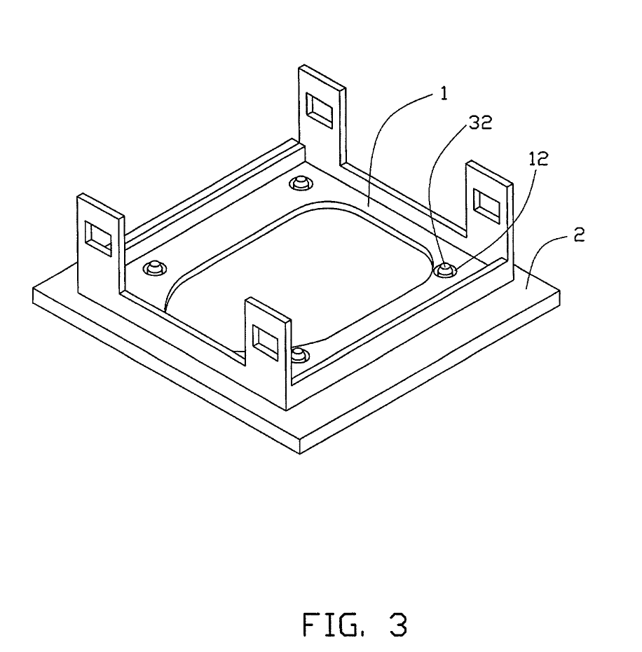

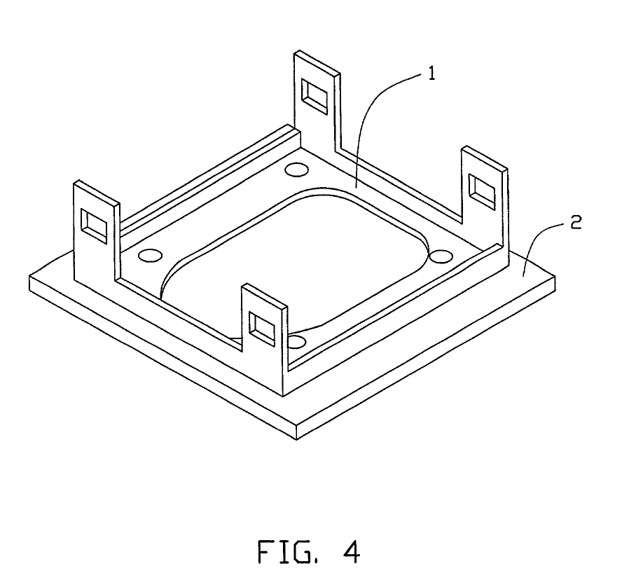

Referring to FIGS. 2-4, in assembly, the back plate 3 is firstly combined with the circuit board 2. The back plate 3 is mounted to an underside of the circuit board 2. The posts 32 of the back plate 3 are inserted through the through holes 22 of the circuit board 2. The retention module 1 is placed on a top side of the circuit board 2. The posts 32 are inserted through the countersink holes 12 of the retention module 1. The retention module 1, circuit board 2 and back plate 3 are held together, and the cone-shaped ends of the posts 32 which protrude above the countersink holes 12 are heated and melted to fill at least portions of the countersink holes 12. After the melted cone-shaped ends have solidified, the retention module 1, circuit board 2 and back plate 3 are firmly and securely combined together.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. Securing means adapted to accommodate a heat dispersing device and having a circuit board sandwiched therein, the securing means comprising:
a retention module having a plurality of holes defined therein; and
a plastic back plate having a plurality of posts extending upwardly therefrom, said posts being adapted to extend through the circuit board and the holes of the retention module, upper ends of the posts being adapted to be melted thereby firmly combining the retention module, circuit board and back plate together.

2. The securing means as described in claim 1, wherein the holes of the retention module are countersink holes.

3. The securing means as described in claim 1, wherein the retention module has a rectangular base and four columns extending upwardly from four corners of the base.

4. The securing means as described in claim 1, wherein the back plate is generally rhomboid-shaped.

5. The securing means as described in claim 4, wherein the posts extend upwardly from respective extremities of the back plate.

6. The securing means as described in claim 1, wherein a plurality of ribs is formed on the back plate.

7. The securing means as described in claim 1, wherein each of the posts has a cone-shaped upper end.

8. An electrical combination, comprising:
a circuit board defining a plurality of holes therein;
a heat sink retention module placed on a top side of the circuit board, the retention module having a rectangular base and plural columns extending upwardly from four corners of the base respectively, each of the columns defining a locking slot therein, the base defining a plurality of holes therein; and
a plastic back plate mounted on an underside of the circuit board, the back plate having a plurality of posts extending upwardly through the holes of the circuit board and the holes of the base of the retention module, each of the posts having an upper end which is melted to fill at least a portion of a corresponding hole of the base thereby securing the retention module, circuit board and back plate together.

9. The securing means as described in claim 8, wherein each of the holes in the base of the retention module is a countersink hole.

10. A method of assembling a retention module on a printed circuit board, comprising the steps of:
providing a printed circuit board defining opposite surfaces with a plurality of first through holes around a periphery of a specific area thereof;
positioning a retention module on one surface, said retention module including a base with a plurality of second through holes in alignment with the corresponding first through holes, respectively; and
positioning a back plate on the other surface, said back plate including a plurality of posts respectively extending through both the first and second through holes with thereof distal ends melted and expanded to fasten to the retention module wherein the back plate cooperates with the retention module to sandwich the printed circuit board therebetween.
